(19) United States
(12) Patent Application Publication
(10) Pub. No.: US 2009/0110807 A1
(43) Pub. Date: Apr. 30, 2009

(54) METHOD FOR COATING AND APPARATUS

(75) Inventor: MICHAEL KOENIG, FRANKFURT AM MAIN (DE)

Correspondence Address: PATTERSON & SHERIDAN, L.L.P., 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/251,157

(22) Filed: Oct. 14, 2008

Related U.S. Application Data
(60) Provisional application No. 60/982,631, filed on Oct. 25, 2007.

(30) Foreign Application Priority Data
Oct. 25, 2007 (EP) 07020928.3

(51) Int. Cl. B05D 5/12; C23C 16/54

(52) U.S. Cl. 427/69; 118/722

(57) ABSTRACT

The invention relates to thin-film generating. A method is provided for coating a substrate with an evaporation material, the evaporation material comprising one or more metals chosen from the group consisting of light metals; noble metals; poor metals; alkaline earth metals; transition metals from the VI subgroup or VIII subgroup; and lanthanides, with the steps of providing the evaporation material, a portion of the evaporation material being oxidized; providing a reducing agent different from the evaporation material; heating the evaporation material and the reducing agent; wherein the evaporation material and the reducing agent are chosen such that due to the presence of the reducing agent the portion of the oxidized evaporation material is reduced and/or that the evaporation temperature of the oxide of the reducing agent is lower than or equal to the evaporation temperature of the evaporation material.

### CROSS-REFERENCE TO RELATED APPLICATION

This application claims benefit of U.S. provisional patent application Ser. No. 60/982,631 filed Oct. 25, 2007, which is herein incorporated by reference in its entirety.

### FIELD OF THE INVENTION

The invention generally relates to thin-film forming apparatuses and methods for thin film forming. Particularly, it relates to a method for coating a substrate and an evaporation apparatus for evaporation of metals. More specifically, it relates particularly to an evaporation apparatus, and a method of use thereof for the production of organic light emitting diodes (OLEDs).

### BACKGROUND OF THE INVENTION

For thin-film coating of a material on a substrate, a thermal evaporator can be used. For example, coatings with metal films, which e.g., provide a capacitor of a large panel display or a protective layer on a flexible substrate or web, can be applied with evaporators.

In particular, organic evaporators are an essential tool for certain production types of OLEDs. OLEDs are a special type of light-emitting diodes in which the emissive layer comprises a thin-film of certain organic compounds. Such systems can be used in television screens, computer displays, portable system screens, and so on. OLEDs can also be used for general room illumination. The range of colors, brightness, and viewing angles possible with OLED displays are greater than that of traditional LCD displays because OLED pixels directly emit light and do not require a back light. Therefore, the energy consumption of OLED display is considerably less than that of traditional LCD displays. Further, the fact that OLEDs can be coated onto flexible substrates opens the door to new applications such as roll-up displays or even displays embedded in clothing.

In general, the stack of emissive layers and conductive layers of an OLED is sandwiched by electrodes. One of the typical electrode materials is a light metal such as aluminum. In order to coat the substrate with a layer of aluminum it is known to evaporate pure aluminum. However, practice shows that evaporating the aluminum leads to two major problems. One is that the evaporation unit used such as a crucible wears quickly and therefore has to be replaced often, that is, in the order of magnitude of ten hours. Another problem is that the evaporation material inlet for supplying the evaporation unit with evaporation material tends to get blocked. Similar problems arise with other materials.

### SUMMARY OF THE INVENTION

According to an aspect of the present invention, a method is provided for coating a substrate with an evaporation material with the steps of providing an evaporation material, the evaporation material comprising one or more metals chosen from the group consisting of light metals; noble metals; poor metals; alkaline earth metals; transition metals from the VI subgroup or VIII subgroup; and lanthanides; a portion of the evaporation material being oxidized; providing a reducing agent different from the evaporation material; and heating the evaporation material and the reducing agent; wherein the evaporation material and the reducing agent are chosen such that due to the presence of the reducing agent the portion of the oxidized evaporation material is reduced.

The phrase “a portion of the oxidized evaporation material” typically refers to at least 0.1% per weight of the evaporation material, more typically to at least 0.15% per weight, even more typically to at least 0.196% per weight. The phrase “the portion of the oxidized evaporation material is reduced” refers typically to a reduction of at least 20%, more typically of at least 50%, even more typically of at least 90%, and even more typically of at least 95%. In general, during the reduction of the portion of the oxidized evaporation material, the reducing agents and the oxides of the evaporation material react to the evaporation material and oxides of the reducing agent. This reaction takes typically place in the melt. That is, according to typical embodiments described herein, the crucible is heated to a temperature that is below the evaporating temperature of the oxide of the evaporation material such as aluminum oxide or silver oxide.

According to another aspect of the invention, a method is provided for preventing the deposition of an oxide of an evaporation material on an evaporation unit during the coating of a substrate with the evaporation material by use of a reducing agent with the evaporation material comprising one ore more metals chosen from the group consisting of light metals; noble metals; poor metals; alkaline earth metals; transition metals from the VI subgroup or VIII subgroup; and lanthanides.

According to another aspect of the present invention, a method is provided for preventing the oxidation of an evaporation material during the coating of a substrate with the evaporation material by use of a reducing agent that is different from the evaporation material, the evaporation material comprising one ore more metals chosen from the group consisting of light metals; noble metals; poor metals; alkaline earth metals; transition metals from the VI subgroup or VIII subgroup; and lanthanides.

According to another aspect of the invention, a method is provided for coating a substrate with an evaporation material with the steps of providing an evaporation material, the evaporation material comprising one or more metals chosen from the group consisting of the group consisting of light metals; noble metals; poor metals; alkaline earth metals; transition metals from the VI subgroup or VIII subgroup; and lanthanides; providing a reducing agent different from the evaporation material; and heating the evaporation material and the reducing agent; wherein the evaporation material and the reducing agent are chosen such that the evaporation temperature of the oxide of the reducing agent is lower than or equal to the evaporation temperature of the evaporation material.

According to another aspect of the present invention, an evaporation apparatus is provided for evaporating an evaporation material on a substrate, the apparatus having an evaporation unit, an evaporation material and a reducing agent, the reducing agent being different from the evaporation material, wherein the evaporation material comprises one or more metals chosen from the group consisting of light metals; noble metals; poor metals; alkaline earth metals; transition metals from the VI subgroup or VIII subgroup; and lanthanides and wherein the evaporation material and the reducing agent are chosen such that the evaporation temperature of the oxide of the reducing agent is lower than or equal to the evaporation temperature of the evaporation material.

According to yet another aspect of the present invention, an evaporation apparatus is provided for evaporating an evaporation material on a substrate, the apparatus having an evaporation unit, an evaporation material with a portion of the evaporation material being oxidized, and a reducing agent different from the evaporation material wherein the evaporation material comprises one or more metals chosen from the group consisting of light metals; noble metals; poor metals; alkaline earth metals; transition metals from the VI subgroup or VIII subgroup; and lanthanides, and wherein the evaporation material and the reducing agent are chosen such that due to the presence of the reducing agent the portion of the oxidized evaporation material is reduced.

Further advantages, features, aspects and details that can be combined with the above embodiments are evident from the dependent claims, the description and the drawings.

Embodiments are also directed to apparatuses for carrying out the disclosed methods and including apparatus parts for performing each described method steps. These method steps may be performed by way of hardware components, a computer programmed by appropriate software, by any combination of the two or in any other manner. Furthermore, embodiments are also directed to methods by which the described apparatus operates or by which the described apparatus is manufactured. It includes method steps for carrying out functions of the apparatus or manufacturing parts of the apparatus.

### BRIEF DESCRIPTION OF THE DRAWINGS

Some of the above indicated and other more detailed aspects of the invention will be described in the following description. Also, some aspects are illustrated with reference to the figures. Therein:

FIG. 1 shows a schematic cross-sectional view of a first embodiment of an evaporation apparatus according to the present invention.

FIG. 2 shows a schematic cross-sectional view of a second embodiment of an evaporation apparatus according to the present invention.

FIG. 3 shows a schematic cross-sectional view of a third embodiment of an evaporation apparatus according to the present invention with several crucibles.

### DETAILED DESCRIPTION OF THE INVENTION

Without limiting the scope of the present application, in the following aluminum is described as a material to be deposited on a substrate. The invention is still directed to light metals; noble metals; poor metals; alkaline earth metals; transition metals from the VI subgroup or VIII subgroup; lanthanides, alloys or other materials to be evaporated and used for coating a substrate. Further, without limiting the scope of the present invention, a substrate is typically referred to as a glass substrate as often used for display technology, e.g., displays. Embodiments of the present invention can be applied to thin-film vapor deposition on other substrates and for other technologies, e.g., for flexible substrates or webs. Embodiments of the present invention, in particular the method and the use according to the present invention can be used in the production of OLEDs. In general, the substrate which is coated with the method according to the present invention may comprise at least one layer of organic material.

In particular, according to the embodiments described herein, the evaporation material may be chosen from the group consisting of aluminum (Al), silver (Ag), chromium (Cr), copper (Cu), indium (In), iron (Fe), magnesium (Mg), nickel (Ni), tin (Sn), and ytterbium (Yb).

Typically, the evaporation apparatus according to the present invention is for coating a substrate that has already been coated with organic material or that is still to be coated with organic material. That is, the substrate may be organic light emitting diodes in production.

The term “crucible” as used in the present application shall be understood as a unit capable of evaporating material that is fed to the crucible when the crucible is heated. In other words, a crucible is defined as a unit adapted for transforming solid material into vapor. Within the present invention, the term “crucible” and “evaporation unit” are used synonymously.

Typically, the evaporation material is a metal such as aluminum. Further, the evaporation material may also be an alloy of two or more metals. The evaporation material is the material that is evaporated during the evaporation and with which the substrate is coated. The evaporation unit according to the present invention is typically heatable to a temperature of between 1,300° C. and 1,600° C. such as 1560° C.

Within the following description of the drawings, the same reference numbers refer to the same components. Generally, only the differences with respect to the individual embodiments are described.

Typically, the material to be evaporated is evaporated thermally in the embodiments of the present invention.

In general, and particularly for large panel displays, a substrate, which e.g., can be provided as a large and relatively thin glass plate, is typically vertically positioned in a coating process and coated with a vertical evaporator. The term “relatively thin” in this context refers to typical glass thicknesses of between 0.5 mm and 4.0 mm, typically between 0.5 mm and 1.2 mm such as between 0.5 mm and 0.7 mm or between 0.7 mm and 1.2 mm. The term “vertical evaporator” shall be defined as an evaporator arranged and adapted for coating a vertically oriented substrate. Further, the term “substrate” shall also include films, foils, objects and the like.

Vertical evaporation as taught by the present invention allows for the continuous in-line production of coated substrates, such as OLEDs. More particularly, vertical evaporation allows the coating of large substrates and an effective prevention of contamination particles on the substrate. Generally, the present invention allows the coating of substrates having arbitrary length and height. In typical embodiments, one evaporator is provided per 30-40 cm height of the substrate. Height in this context refers to the vertical dimension of the substrate as positioned in the evaporation apparatus. For instance, a substrate with a height of 80 cm can be evaporated with an evaporation apparatus having two or three vertical evaporators positioned one above the other.

According to the present invention, a substrate is coated with an evaporation material such as a light metal, e.g., aluminum. Typically, the coating on the substrate shall include exclusively this evaporation material. In this context, “exclusively this material” is to be understood as that this evaporation material shall amount to at least 90.0%, typically at least 95.0% and more typically at least 99.0% of the coating such as at least 99.99%. The evaporation material on the substrate may be in an atomic and/or molecular form whereas the molecular form is typically an oxide of the material. In general, however, the present invention allows reducing the proportion of the oxide of the material in relation to the atomic form of the material in the coating. It is therefore generally typical for the present invention that the coating comprises less than 1%, more typically less than 0.5% of the evaporation material oxide, even more typically less than 0.2% of the evaporation material oxide.

As set forth above, practice reveals problems when evaporating a metal such as aluminum. Research has been conducted in order to find out the reason for the quick wear of the crucibles and the blocking of the evaporation material inlets in the crucible. It has been found that these problems stem from the presence of metal oxide on the crucible and the evaporation material inlet; also, evaporation material oxide residues on the crucible handicap the re-wettability of the crucible. This fact is surprising as the evaporation takes place in a clean vacuum atmosphere and only highly pure aluminum (e.g., with a purity of 99.95%) is typically fed to the crucible. Therefore, the forming of metal oxide could not be expected.

Analysis revealed that the highly pure aluminum wire comprises an oxide layer with a thickness in the range of between 0.1 to 0.5 micrometer formed on the outer circumference of the wire. The presence of this oxide layer is one explanation for the presence of the oxide during evaporation. Another possible explanation is the impurity of the vacuum. Parts in the vacuum chamber may be made of materials comprising bound oxygen. Some of the oxygen may diffuse into the vacuum chamber.

Within the present application, oxygen refers to oxygen that is typically bound in molecules such as O₂, O₃ or Al₂O₃. Without going into detail where the oxygen comes from, the finding is important that the presence of the oxide in the evaporation process is partly responsible for the problems set forth above.

In order to reduce the forming of oxides of the material, according to the present invention, a reducing agent is provided. The effect is as follows: Due to the presence of the reducing agent, the oxygen present “prefers” linking with the reducing agent instead of the evaporation material. A more sophisticated explanation for the term “prefer” will be given in the following.

In the field of alkali metal evaporation, it is typical to add a reducing agent to the evaporation material. This is due to the fact that alkali metals are highly reactive. When in contact with air, they would react instantly. Therefore, they are typically provided as alkali metal chromates for evaporation. Nevertheless, it is desired to coat a substrate with a pure alkali metal layer and not with a layer of alkali metal chromate. Knowing that alkali metal chromates are strong oxidants, a reducing agent is added to the alkali metal chromate allowing the generation of a pure alkali metal layer.

This example highlights the differences of the alkali metal evaporation field and the technical field of the present invention: Light metals such as aluminum, noble metals such as silver, copper or gold; poor metals such as tin or indium; alkaline earth metals such as magnesium; transition metals from the VI subgroup such as chromium or from the VIII subgroup such as iron or nickel; or a lanthanide such as ytterbium can be evaporated directly. In other words, there is no need for providing these materials as ancillary compounds of any type. Therefore, there is no need to provide a reducing agent in order transform the ancillary compound back to the metal itself Hereto in contrary, the metals as used according to embodiments described herein are provided as such. Further, in contrary to the chromates, metals such as aluminum and silver are strong reducing agents due to their high reactivity with oxygen whereas their oxides are stable.

Within the present invention, the phrase “react to an oxide of the material” and the phrase “the material is oxidized” as well as synonymously used phrases refer to the chemical reaction wherein an oxidant removes electrons from another substance. Oxidants are typically chemical substances with elements in high oxidation numbers or highly electronegative substances that can gain one or two extra electrons by oxidizing a substance. More particularly, the oxidant is typically oxygen within the present application. Substances that have the ability to reduce other substances are said to be reductive and are synonymously named reducing agents, reductants, or reducers herein. The reducing agent transfers electrons to another substance, and is thus oxidized itself. In other word, the reducing agent “donates” electrons.

For instance, particularly electropositive elemental metals can be used as reducing agents according to the present invention. Experiments have shown that magnesium (Mg) is particularly suitable. Further, lithium (Li) is also particularly suitable. Besides, sodium (Na) and iron (Fe) shall be mentioned as suitable materials. Further examples are given in the following and in the claims. These metals donate electrons readily. In summation, the reducing agent transfers electrons to the oxidant. Thus, in the reaction, the reducing agent loses electrons and is oxidized; the oxidant or oxidizing agent gains electrons and is reduced.

The reducing agent used according to embodiments of the present invention has to be chosen such that the oxygen present prefers to oxidize the reducing agent instead of the evaporation material. This condition has to be fulfilled for a vacuum atmosphere and the temperature necessary to evaporate the evaporation material which is typically up to 1,600° C. Vacuum atmosphere shall refer to a pressure of between 10⁻² mbar and 10⁻⁶ mbar.

Hence, the reducing agent has typically an electronegativity which is smaller than the electronegativity of the evaporation material. For instance, the reducing agent may be chosen from the group of base metals. Optionally, the reducing agent shall be chosen such that the evaporating temperature of the oxide of the reducing agent shall be smaller or equal to the evaporating temperature of the evaporation material.

As it is well known to the person skilled in the art, there are several ways of defining and calculating the electronegativity of a substance such as the Pauling electronegativity, Mulliken electronegativity, Allred-Rochow electronegativity, Sanderson electronegativity and Allen electronegativity. With respect to some embodiments of the present application, the focus is primarily on the comparison of the electronegativity of the evaporation material and the electronegativity of the reducing agent. Hence, in many cases there is no need for using a specific electronegativity definition. However, in those cases where reference to a definition is indispensable, reference is made to the Allred-Rochow definition.

Table 1 gives some examples of electronegativities for selected elements. For exemplary purposes, the elements are selected such that their respective electronegativity is smaller or equal to the electronegativity of aluminum which is given with 1.47 eV. The values are taken from www.wikipedia.de on Apr. 24, 2007 (“Elektronegativität” ).

TABLE 1
The electronegativity [eV] of a selected group of materials according to the Allred-
Rochow definition.

| | group | | | | | | | | | | | | |
|---|---|---|---|---|---|---|---|---|---|---|---|---|---|
| period | 1 | 2 | 3 | 4 | 5 | 6 | 7 | 8 | 9 | 10 | 11 | 12 | 13 |
| 2 | Li | | | | | | | | | | | | |
| | 0.97 | | | | | | | | | | | | |
| 3 | Na | Mg | | | | | | | | | | | Al |
| | 1.01 | 1.23 | | | | | | | | | | | 1.47 |
| 4 | K | Ca | Sc | Ti | V | | | | | | | | |
| | 0.91 | 1.04 | 1.20 | 1.32 | 1.45 | | | | | | | | |
| 5 | Rb | Sr | Y | Zr | Nb | Mo | Tc | Ru | Rh | Pd | Ag | Cd | |
| | 0.89 | 0.99 | 1.11 | 1.22 | 1.23 | 1.30 | 1.36 | 1.42 | 1.45 | 1.30 | 1.42 | 1.46 | |
| 6 | Cs | Ba | La | Hf | Ta | W | Re | | | Pt | Au | Hg | Tl |
| | 0.86 | 0.97 | 1.10 | 1.23 | 1.33 | 1.40 | 1.46 | | | 1.42 | 1.42 | 1.44 | 1.44 |
| 7 | Fr | Ra | | | | | | | | | | | |
| | 0.86 | 0.97 | | | | | | | | | | | |

In typical embodiments of the present invention, the reducing agent is chosen such that its electronegativity is smaller than the electronegativity of the evaporation material. More typically, the difference between the electronegativity of the evaporation material and the electronegativity of the reducing agent is maximized. For instance, the electronegativity of Lithium is 0.97 according to the Allred-Rochow definition (0.98 according to the Pauling definition, see table 4.10(a) of “Physikalische Chemie” by Peter W. Atkins, 1990) and the electronegativity of magnesium is 1.23 according to the Allred-Rochow definition (1.31 according to the Pauling definition) whereas the electronegativity of aluminum is 1.47 according to the Allred-Rochow definition (1.61 according to the Pauling definition), and the electronegativity of silver (Ag) is 1.42 according to the Allred-Rochow definition (1.9 according to the Pauling definition).

Further materials interesting as reducing agents are copper (Cu) and silicon (Si).

According to another aspect of the invention, the reducing agent is chosen such that the evaporation temperature of the oxide of the reducing agent is lower than or equal to the evaporation temperature of the evaporation material. This way the formed oxide can be prevented from remaining on the crucible and/or the crucible inlet when the crucible is heated to the evaporation temperature. Evaporation temperature in this context shall refer to the temperature necessary on the crucible in order to evaporate the evaporation material.

In the event that the melting temperature of the reducing agent oxide is below the evaporation temperature, the crucible inlet does not get blocked with oxide residues and no oxide residues are formed on the crucible leading to a declined re-wettability. Hence, according to some embodiments, the reducing agent is chosen such that the melting temperature of the oxide of the reducing agent is lower than or equal to the evaporation temperature of the evaporation material.

For example, the reducing agent is typically chosen such that the evaporation temperature of the oxide of the reducing agent is typically smaller than the evaporation temperature of the evaporation material and more typically more than 50° smaller than the evaporation temperature of the evaporation material. According to another embodiment of the present invention, the evaporation temperature of the oxide of the reducing agent is lower than or equal to the evaporation temperature of the oxide of the evaporation material. This way, it may be guaranteed that the oxide residues are evaporated and do not remain on the crucible and its inlet. According to yet another embodiment of the present invention, the evaporation temperature of the oxide of the reducing agent is lower than or equal to the evaporation temperature of the reducing agent.

Further, in view of economic constraints, it is typical to choose those reducing agents whose purchase price is as low as possible.

Further, another constraint is typically that the reducing agent is chosen such that the deposition of the oxide of the reducing agent on the substrate and/or the deposition of the reducing agent itself on the substrate does not lead to a minor quality of the coating of the substrate.

According to the Allred-Rochow definition, the electronegativity is related to the charge experienced by an electron on the “surface” of an atom: the higher the charge per unit area of atomic surface, the greater the tendency of that atom to attract electrons. The definition is based on the idea that the electronegativity is proportional to the electrostatic force acting on the respective outer electrons by the effective nuclear charge. As the inner electrons shield some of the nuclear charge, the effective nuclear charge acting on the electron surface is smaller than the nuclear charge. In addition, the force is, according to Coulomb's law, proportional to the reciprocal value of the square of the distance between nucleus and outer electron.

According to typical embodiments of the present invention, the evaporation material and the reducing agent are provided as an alloy. Typically, the proportion of the reducing agent in the alloy is between 0.1% and 2%, more typically between 0.15% and 1.5% such as between 0.2% and 1%. Typically, the proportion of the evaporation material in the alloy is between 98% and 99.9%, more typically between 98.5% and 99.85% such as between 99% and 99.8%.

In other embodiments of the present invention, the evaporation material and the reducing agent are provided separately, e.g., as a mixture with pellets of the evaporation material and pellets of the reducing agent. Typically, the average diameter size of pellets is in the order of magnitude of lmm such as between 1 mm and 2 mm. In those embodiments where the evaporation material is silver, the use of pellets is particularly advantageous since silver has a high heat conductivity which may cause problems when providing the material by wire.

Another possibility to supply the evaporation material and the reducing agent separately is to feed the crucible with one wire of the evaporation material and one separate wire of the reducing agent. In this case, the feeding rates and/or the wire diameters have to be chosen such that a desired ratio of the evaporation material and the reducing agent is effected. Typically, the proportion of the reducing agent in the alloy is between 0.1% and 2%, more typically between 0.15% and 1.5% such as between 0.2% and 1%. Typically, the proportion of the evaporation material in the alloy is between 98% and 99.9%, more typically between 98.5% and 99.85% such as between 99% and 99.8%. For instance, if the feeding wire cross sectional area of the reducing agent is one fifth of the feeding wire cross sectional area of the evaporation material, and the feeding rate of the reducing agent wire is one twentieth of the feeding rate of the evaporation material, about 1% of the vapor generated in the crucible is the reducing agent whereas the rest, i.e., 99%, of the generated vapor is the evaporation material.

In typical embodiments, the diameter of the feeding wire for feeding to the crucible is chosen between 0.5 mm and 2.0 mm, more typically between 1.0 mm and 1.5 mm. These dimensions may refer to a feeding wire being a combination of the evaporation material and the reducing agent, or an alloy of the evaporation material and the reducing agent. These dimensions may also refer to several feedings wires wherein one feeding wire is made of the evaporation material and another feeding wire is made of the reducing agent.

In other embodiments of the present invention, only one wire is fed to the crucible wherein the wire comprises two layers with the layer that is larger with respect to the layer volume being the evaporation material and the layer that is smaller with respect to the layer volume being the reducing agent.

According to another aspect of the invention, the reducing agent is typically chosen such that the oxide of the reducing agent has a smaller evaporation temperature than the evaporation material. This is advantageous in that the oxide is evaporated without heating the crucible more than necessary for evaporating the evaporation material.

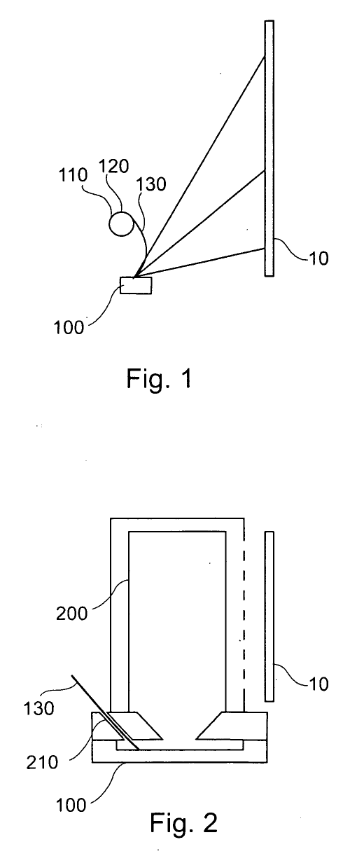

FIG. 1 shows a schematic cross-sectional side view of an evaporation apparatus according to the present invention. The crucible 100 is fed with a wire 130 of an alloy of the evaporation material and the reducing agent. In the present embodiment, an alloy of aluminum and magnesium with a ratio of 99.5 to 0.5 is fed to the crucible. The wire is uncoiled from the coil 120 which is mounted to the coil carrier 110. The coil carrier typically comprises means for uncoiling the wire at a constant speed that can be set, for instance, by the operator of the evaporation apparatus. Typical feeding rates of the wire are in the range of between 50 cm/min and 150 cm/min, more typically between 70 cm/min and 100 cm/min. The wire 130 of the material to be deposited is uncoiled from the wire coil 120 and fed to the crucible 100 where it is evaporated.

The crucible 100 is heated in order to generate a vapor and to coat the substrate 10 with the evaporation material. Typically, the crucible is heated by applying a voltage to the electrodes of the crucible which are positioned at opposite sides of the crucible. Generally, according to embodiments described herein, the material of the crucible is conductive. Typically, the material used as crucible material is temperature resistant to the temperatures used for melting and evaporating. Typically, the crucible of the present invention is made of one or more materials selected from the group consisting of metallic boride, metallic nitride, metallic carbide, non-metallic boride, non-metallic nitride, non-metallic carbide, nitrides, titanium nitride, borides, graphite, TiB₂, BN, B₄C, and SiC. Typical lengths of the crucible are in the range of 90 mm and 350 mm, more typically between 90 mm and 180 mm such as 130 mm whereas typical widths of the crucible are in the range of 20 mm and 40 mm such as 30 mm. Typical heights of the crucible are in the range of 5 mm and 15 mm such as 10 mm.

The material to be deposited is melted and evaporated by heating the evaporation crucible 100. Heating can be conducted by providing a power source (not shown) connected to the first electrical connection and the second electrical connection of the crucible. For instance, these electrical connections may be electrodes made of copper or an alloy thereof. Thereby, heating is conducted by the current flowing through the body of the crucible 100. According to other embodiments, heating may also be conducted by an irradiation heater of an evaporation apparatus or an inductive heating unit of an evaporation apparatus.

For instance, according to embodiments combinable with other embodiments described herein, the evaporation material may be a light metal such as aluminum. In addition or alternatively, it may be a noble metal such as silver, copper or gold. In addition or alternatively, it may be a poor metal such as tin or indium. In addition or alternatively, it may be an alkaline earth metal such as magnesium. In addition or alternatively, it may be a transition metal from the VI subgroup such as chromium. In addition or alternatively, it may be a transition metal from the VIII subgroup such as iron or nickel. In addition or alternatively, it may be a lanthanide such as ytterbium.

In operation, the crucible 100 enables thin film forming of a material on a substrate. According to typical embodiments described herein, the material to be vapor deposited on the substrate can be a metal like a light metal; a noble metal; a poor metal; an alkaline earth metal; a transition metal from the VI subgroup or VIII subgroup; and a lanthanide. In particular, the material to be vapor deposited on the substrate can be a metal like aluminum, silver, copper, ytterbium, or alloys including at least one of these metals.

The temperature on the crucible surface is typically chosen to be in the range of 1,300° C. to 1,600° C., e.g., about 1,560° C. This is done by adjusting the current through the crucible accordingly, or by adjusting the irradiation accordingly. Typically, the crucible material is chosen such that its stability is not negatively affected by temperatures of that range.

As shown in FIGS. 1-3, in typical embodiments of the present invention, the evaporation apparatus is used for vertical evaporation, i.e., with the placement and orientation of the crucible being adapted for coating a vertically oriented substrate. According to typical embodiments of the vertical evaporator according to the present invention, the substrate 10 travels horizontally past the evaporation apparatus crucible 100. Thereby, the evaporation apparatus according to the present invention provides a continuous coating process of the vertically arranged substrate in the horizontal direction. This continuous coating shall be called “in-line coating” within the present application. In order to enable a vertical movement of the substrate, a transportation unit such as a conveyor belt (not shown) or the like is provided to which the substrates can be fixed. Typically, the speed of the substrates is in the range of between 20 cm/min and 200 cm/min, more typically between 80 cm/min and 120 cm/min such as 100 cm/min. In these cases, the means for transporting should be capable of transporting the substrate at those speeds.

It is further generally possible to position a mask (not shown) between the evaporation crucible and the substrate. The mask helps avoid undesired irregularities in the coating thickness. Typical aperture sizes are in the range of 50 mm and 200 mm. Typical aperture shapes are curved. Typically, the aperture is symmetrical in the vertical direction. The aperture is typically positioned such that the center of the evaporation distribution is suppressed. This is due to the fact that, in general, the coating on the substrate shall be as homogeneous as possible and the evaporation distribution is maximal in the center of the distribution.

In typical embodiments of the present invention, the feeding rate at which the material is fed to the crucible and the temperature of the crucible are adjusted such that a substantial part of the solid material melts into material melt.

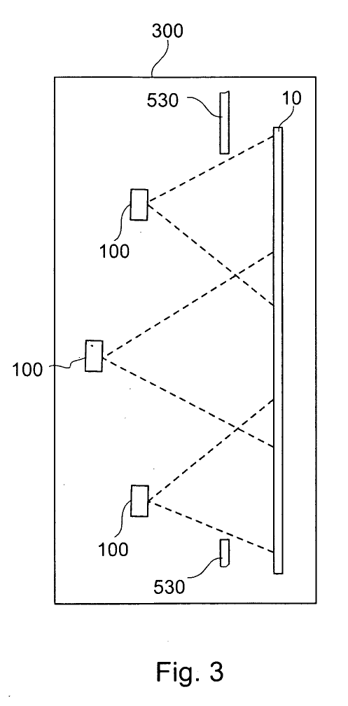

As an embodiment, a method of forming a thin film can be carried out by using an apparatus which is entirely placed in a vacuum chamber with a typical atmosphere of 10-2 to 10-6 mbar. Thereby, the thin film can be vapor deposited on a substrate without contamination from the ambient atmosphere. In order to provide for a vacuum, the evaporator apparatus of the present invention is typically positioned in a vacuum chamber (see embodiment of FIG. 3). The vacuum chamber is typically equipped with vacuum pumps (not shown) and/or tube outlets (not shown) for pumping the air out of the chamber.

As a further example, the embodiments described herein can be utilized for the coating of substrates for display technology or the like. Thereby, substrate size may be as follows. A typical glass substrate and, thereby, also a coating area can have dimensions of about 0.7 mm ×500 mm ×750 mm. Yet, the substrates that can be processed with the present invention can also have a size of about 1500 mm ×1850 mm or even larger such as 2500 mm.

FIG. 2 shows another embodiment of the present invention. A crucible 100 is fed with a wire 130. The wire may be an alloy or comprise two layers of different material, one material being the evaporation material and the other material being the reducing agent. The wire is fed to the crucible via the evaporation material inlet 210. The crucible is heated so that the wire is transformed into vapor. The vapor rises into the evaporation chimney 200 and is deposited on the substrate 10.

FIG. 3 shows an embodiment of an evaporation apparatus having several crucibles. Therein, three evaporation crucibles 100 are provided in front of a substrate 10. It is possible to arrange a respective mask (not shown) between each of the crucibles and the substrate. It is further possible to position separation units such as walls (not shown) between the crucibles. In general, the multitude of crucibles is positioned such that their respective evaporation distribution overlaps with the evaporation distribution of the adjacent crucible(s).

In a typical embodiment, each crucible is loaded with separate material wire. Typically, the wire for all crucibles is made of the same material combination or material alloy. In the embodiment shown in FIG. 3, coil carriers (not shown) can be provided for mounting the coils with the wires of material to be evaporated.

In the embodiment shown in FIG. 3, the vacuum chamber 300 is depicted within which the evaporation apparatus according to the present invention is located. It shall be understood that all embodiments of an evaporation apparatus discussed herein can be positioned within a vacuum chamber. Further, according to typical embodiments of methods disclosed herein, the step of pumping air out of the vacuum chamber is comprised.

According to the embodiment shown in FIG. 3, the three crucibles 100 are positioned displaced to each other. That is, some of the crucibles are positioned closer to the substrate than other crucibles. Typical displacement distances are between 20 and 60 mm. Typically, the displacement distance is between 5% and 15% such as 10% of the distance between crucible and substrate. This interval is to be understood as referring to the distance between the crucible, which is furthest to the substrate, and the substrate minus the distance between the crucible, which is closest to the substrate, and the substrate. The displacement may improve the coating characteristics on the substrate. The positioning of the crucibles may be such that different average directions of the evaporation distributions are taken into account. Typically, the crucibles positioned between other crucibles are positioned further away from the substrate than the crucibles at edge positions as it is exemplarily shown in FIG. 3. Further, in the embodiments with several crucibles, it is possible that one common mask is used that has several apertures, e.g., each for one crucible.

Further, in embodiments with several crucibles the number of crucibles is typically optimized in order to have the substrate coated as homogeneously as possible. Generally, the number of crucibles is chosen such that one crucible is assigned to each sub-height of the substrate. The sub-height of the substrate is the height that one crucible can properly coat. Typically, the sub-height is between 30 cm and 40 cm. This can, for instance, result in a number of crucibles of between two and five. For example, it is typical to provide 3-4 crucibles for a substrate with a height of 1100 mm. The height of the substrate in this context refers to the vertical dimension of the crucible as positioned in the vertical evaporation apparatus.

According to the present invention, several effects can be achieved. Due to the use of the reducing agent, the amount of the evaporation material oxide on the crucible and particularly on the evaporation material inlet can be reduced. Further, this guarantees a crucible surface which is wettable for a longer time period due to the reduced amount of evaporation material oxide condensing on the surface. This, in turn, results in a longer operation time of the crucible, reducing particularly the time and costs involved in the operation of the evaporation apparatus of the present invention.

Further, in comparison to the operation of the evaporation apparatus as known in the art, i.e., without the addition of a carefully chosen reducing agent, in some embodiments of the present invention it is possible to reduce the temperature of the crucible during evaporation. This is particularly relevant in those cases where the evaporation temperature of the evaporation material oxide is higher than the evaporation temperature of the evaporation material itself. Further, in some embodiments of the present invention, the crucibles tend less to the generation of spillings on the substrate due to the reduced amount of condensed oxide on the crucibles.

While the foregoing is directed to embodiments of the invention, other and further embodiments of the invention may be devised without departing from the basic scope thereof, and the scope thereof is determined by the claims that follow.

1. Method for coating a substrate with an evaporation material, comprising:
providing an evaporation material, the evaporation material comprising one or more metals chosen from the group consisting of:
light metals;
noble metals;
poor metals;
alkaline earth metals;
transition metals from the VI subgroup or VIII subgroup; and
lanthanides;
providing a reducing agent different from the evaporation material; and
heating the evaporation material and the reducing agent;
wherein the evaporation material and the reducing agent are chosen such that the evaporation temperature of an oxide of the reducing agent is lower than or equal to the evaporation temperature of the evaporation material.

2. Method for coating a substrate with an evaporation material, comprising:
providing an evaporation material, the evaporation material comprising one or more metals chosen from the group consisting of:
light metals;
noble metals;
poor metals;
alkaline earth metals;
transition metals from the VI subgroup or VIII subgroup; and
lanthanides; a portion of the evaporation material being oxidized;
providing a reducing agent different from the evaporation material; and
heating the evaporation material and the reducing agent;
wherein the evaporation material and the reducing agent are chosen such that due to the presence of the reducing agent the portion of the oxidized evaporation material is reduced.

3. Method for preventing the deposition of an oxide of an evaporation material on an evaporation unit during the coating of a substrate with the evaporation material by use of a reducing agent different from the evaporation material wherein the evaporation material comprises one or more metals chosen from the group consisting of:
light metals;
noble metals;
poor metals;
alkaline earth metals;
transition metals from the VI subgroup or VIII subgroup; and
lanthanides.

4. Method according to claim 2, wherein the evaporation temperature of the oxide of the reducing agent is lower than or equal to the evaporation temperature of the evaporation material.

5. Method according to claim 2, wherein the evaporation material is one or more metals chosen from the group consisting of aluminum, silver, and ytterbium.

6. Method according to claim 2, wherein the evaporation material is chosen from the group consisting of chromium, copper, indium, iron, magnesium, nickel, and tin.

7. Method according to claim 2, wherein the evaporation temperature of the oxide of the reducing agent is lower than or equal to the evaporation temperature of the oxide of the evaporation material.

8. Method according to claim 2, wherein a part of at least 20% of the reducing agent reacts to an oxide of the reducing agent.

9. Method according to claim 2, wherein the electronegativity of the evaporation material is larger than the electronegativity of the reducing agent.

10. Method according to claim 2, wherein the reducing agent is a base metal.

11. Method according to claim 2, wherein the reducing agent is magnesium.

12. Method according to claim 2, wherein the reducing agent is chosen from the group consisting of lithium, sodium, potassium, rubidium, caesium, calcium, strontium, barium, scandium, yttrium, ytterbium, lanthanum, titanium, zirconium, hafnium, niobium, tantalum, molybdenum, technetium, and ruthenium.

13. Method according to claim 2, wherein the reducing agent is chosen from the group consisting of copper, iron, manganese, and silicon.

14. Method according to claim 2, wherein the relation of the reducing agent and the evaporation material is between 0.1 of the reducing agent to 99.9 of the evaporation material and 2 of reducing agent to 98 of the evaporation material.

15. Method according to claim 2, wherein the evaporation material and the reducing agent are provided as an alloy of the evaporation material and the reducing agent.

16. Method according to claim 2, wherein the evaporation material and the reducing agent are provided in the form of a wire.

17. Method according to claim 2, wherein the evaporation material and the reducing agent are provided in the form of pellets.

18. Method according to claim 2, wherein the method is part of the production of organic light emitting diodes.

19. Apparatus for evaporating an evaporation material on a substrate, comprising:
a heatable evaporation unit;
an evaporation material; and
a reducing agent different from the evaporation material,
wherein the evaporation material comprises one or more metals chosen from the group consisting of:
light metals;
noble metals;
poor metals;
alkaline earth metals;
transition metals from the VI subgroup or VIII subgroup; and
lanthanides, and
wherein the evaporation material and the reducing agent are chosen such that the evaporation temperature of an oxide of the reducing agent is lower than or equal to the evaporation temperature of the evaporation material.

20. Apparatus according to claim 19, wherein the reducing agent is magnesium.

21. Apparatus according to claim 19, wherein the evaporation material is aluminum or silver.
